(19) United States
(12) Patent Application Publication
(10) Pub. No.: US 2025/0038574 A1
(43) Pub. Date: Jan. 30, 2025

(54) WIRELESS CHARGING CIRCUIT

(71) Applicant: SAMSUNG ELECTRONICS CO., LTD., SUWON-SI (KR)

(72) Inventors: Youso Cheon, Suwon-Si (KR); Seokhyeong Ham, Suwon-si (KR); Arom Lee, Suwon-si (KR)

(21) Appl. No.: 18/626,406

(22) Filed: Apr. 4, 2024

(30) Foreign Application Priority Data
Jul. 27, 2023 (KR) 10-2023-0098353

(51) Int. Cl. H02J 50/12; H02J 7/00

(52) U.S. Cl. CPC H02J 50/12; H02J 7/00308; H02J 7/0047; H02J 7/007192

(57) ABSTRACT

A wireless charging circuit wirelessly receives power and includes a power receiving circuit that includes an inductor and a capacitor, a rectifier circuit that rectifies an alternating current voltage received from the power receiving circuit and outputs a rectified voltage, a regulating circuit that outputs a charging voltage that charges a battery using the rectified voltage, an overvoltage protection circuit connected in parallel between the rectifier circuit and the regulating circuit, and a controller that detects the rectified voltage and controls the overvoltage protection circuit. The overvoltage protection circuit includes first and second overvoltage protection circuits. By separating turn-on holding times of the first and second overvoltage protection circuits, the wireless charging circuit is effectively protected from overvoltage and damage to the circuit due to heat generation is prevented.

### CROSS-REFERENCE TO RELATED APPLICATION(S)

This application claims priority under 35 U.S.C. 119(a) from Korean Patent Application No. 10-2023-0098353, filed on Jul. 27, 2023 in the Korean Intellectual Property Office, the contents of which are herein incorporated by reference in their entirety.

### TECHNICAL FIELD

Embodiments of the present inventive concept are directed to a wireless charging circuit.

### DISCUSSION OF THER RELATED ART

Electronic devices typically include batteries that supply a power voltage for operation, and charging circuits for charging the battery using power supplied from an external source. A battery charging method may be classified as a wired charging method that charges a battery by directly connecting a charging terminal to an electronic device, and a wireless charging method that charges a battery without connecting a charging terminal by using power output to a charging pad when an electronic device approaches the charging pad. In a wireless charging method, when an electronic device is not accurately aligned with the wireless charging pad, overvoltage can occur in a wireless charging circuit in the electronic device.

### SUMMARY

An embodiment of the present inventive concept prevents damage to a battery and to the wireless charging circuit by including a first overvoltage protection circuit that includes a current source and a second overvoltage protection circuit that includes a resistor and by alternately turning the first and second overvoltage protection circuits on and off to efficiently generate power loss when overvoltage occurs.

According to embodiments, a wireless charging circuit includes a power receiving circuit that wirelessly receives power and includes an inductor and a capacitor, a rectifier circuit that rectifies an alternating current voltage received from the power receiving circuit and outputs a rectified voltage, a regulating circuit that outputs a charging voltage that charges a battery using the rectified voltage, an overvoltage protection circuit connected in parallel between the rectifier circuit and the regulating circuit, and a controller that detects the rectified voltage and controls the overvoltage protection circuit. The overvoltage protection circuit includes a first overvoltage protection circuit and a second overvoltage protection circuit. The second overvoltage protection circuit is turned off when the first overvoltage protection circuit is turned on, and the second overvoltage protection circuit is turned on when the first overvoltage protection circuit is turned off.

According to embodiments, a wireless charging circuit includes a power receiving circuit that wirelessly receives power and includes an inductor and a capacitor; a rectifier circuit that rectifies an alternating current voltage received from the power receiving circuit and outputs a rectified voltage, a regulator circuit that outputs a charging voltage that charges a battery using the rectified voltage, an overvoltage protection circuit connected in parallel between the rectifier circuit and the regulating circuit, and a controller that detects the rectified voltage and controls the overvoltage protection circuit. The overvoltage protection circuit includes a first overvoltage protection circuit and a second overvoltage protection circuit. The first overvoltage protection circuit is turned on before the second overvoltage protection circuit, and at least one of the first overvoltage protection circuit or the second overvoltage protection circuit is repeatedly turned-on and turned-off.

According to embodiments, a wireless charging circuit includes a power receiving circuit that wirelessly receiving power and includes an inductor and a capacitor, a rectifier circuit that rectifies an alternating current voltage received from the power receiving circuit and outputs a rectified voltage, a regulating circuit that outputs a charging voltage that charges a battery using the rectified voltage, at least one first overvoltage protection circuit connected in parallel between the rectifier circuit and the regulating circuit and that includes a current source, at least one second overvoltage protection circuit connected in parallel between the rectifier circuit and the regulating circuit in parallel and that includes a resistor, and a controller that detects the rectified voltage and controls the overvoltage protection circuit. The controller turns on the first overvoltage protection circuit when the overvoltage protection circuit satisfies a first operating condition, turns off the first overvoltage protection circuit and turns on the second overvoltage protection circuit when the overvoltage protection circuit satisfies a second operating condition, and turns on one of the first overvoltage protection circuit or the second overvoltage protection circuit.

### BRIEF DESCRIPTION OF DRAWINGS

FIG. 1 is a diagram of a wireless charging system according to an embodiment.

FIG. 2 is a block diagram of a wireless charging system according to an embodiment.

FIG. 3 is detailed block diagram of a wireless charging system according to an embodiment.

FIG. 4 is a schematic circuit diagram of a wireless charging system according to an embodiment.

FIG. 5 presents graphs that illustrate a change in rectified voltage and an operation of a switch in an overvoltage protection circuit as functions of time, according to an embodiment.

FIGS. 6 to 12 are graphs that illustrate an operation of a switch in an overvoltage protection circuit as a function of time, according to embodiments.

FIG. 13 is a schematic circuit diagram of an overvoltage protection circuit according to an embodiment.

FIG. 14 presents graphs that illustrate operations of switches in the overvoltage protection circuit of FIG. 13 as a function of time, according to an embodiment.

FIG. 15 is a graph of temperature changes of a wireless charging circuit and a resistor as a function of time while an overvoltage protection circuit operates, according to an embodiment.

FIG. 16 is a block diagram of an electronic device according to an embodiment.

FIG. 17 is a flowchart of an operation process of an overvoltage protection circuit according to an embodiment.

FIG. 18 is a flowchart of an operation process of an overvoltage protection circuit according to an embodiment.

### DETAILED DESCRIPTION

Hereinafter, embodiments will be described with reference to the accompanying drawings.

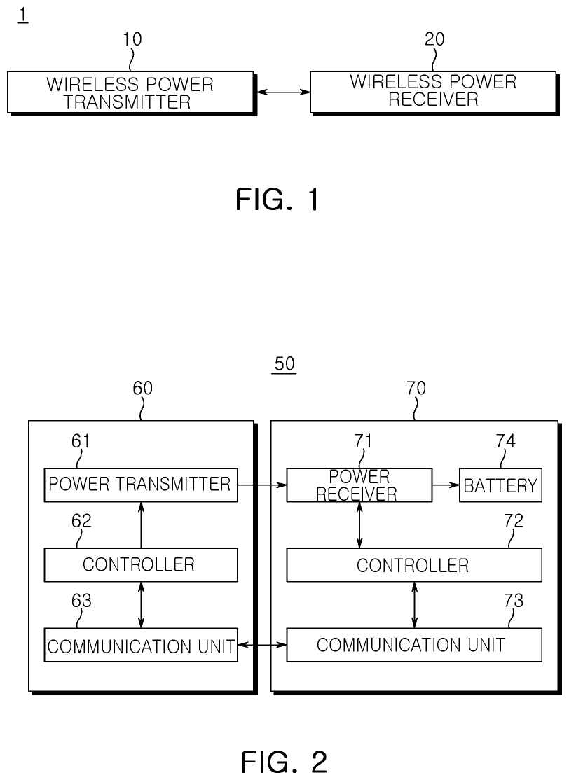

FIG. 1 is a diagram of a wireless charging system according to an embodiment.

Referring to FIG. 1, in an embodiment, a wireless charging system 1 includes a wireless power transmitter 10 and a wireless power receiver 20. As in an embodiment illustrated in FIG. 1, there may be one wireless power receiver 20, but embodiments are not necessarily limited thereto. The wireless power receiver 20 may be implemented as a mobile communication terminal, PDA, PMP, smart phone, or the like, and includes a wireless charging circuit.

The wireless power transmitter 10 is electrically connected to the wireless power receiver 20. In an embodiment, the wireless power transmitter 10 transmits wireless power in the form of electromagnetic waves to the wireless power receiver 20. In addition, the wireless power transmitter 10 can perform bidirectional communication with the wireless power receiver 20. For example, the wireless power receiver 20 transmits a signal that requests wireless power transmission, information for wireless power reception, state information of the wireless power receiver 20, control information of the wireless power transmitter 10, etc., to the wireless power transmitter 10. The wireless power transmitter 10 transmits power to the wireless power receiver 20 based on the received information.

The wireless power receiver 20 receives wireless power from the wireless power transmitter 10 and charges a battery in the wireless power receiver 20. The wireless power transmitter 10 and the wireless power receiver 20 should be disposed in the designed positions to be properly charged. For example, when the wireless power transmitter 10 is not disposed in a designed location, the wireless power receiver 20 receives more power than the requested power.

Overvoltage can occur in the wireless charging circuit in the wireless power receiver 20, and the circuit is protected by inducing power loss through an overvoltage protection circuit. In an embodiment, the overvoltage protection circuit includes a current source and a resistor connected in parallel, and alternately turns on each of the current source and the resistor. Therefore, the wireless charging circuit is protected from overvoltage by inducing an efficient power loss, and an internal circuit in the wireless power receiver 20 is protected from heat generated by a resistor.

FIG. 2 is a block diagram of a wireless charging system according to an embodiment.

In an embodiment, a wireless charging system 50 includes a wireless power transmitter 60 and a wireless power receiver 70. The wireless power transmitter 60 includes a power transmitter 61, a controller 62, and a communication unit 63. The wireless power receiver 70 includes a power receiver 71, a controller 72, a communication unit 73, and a battery 74.

The power transmitter 61 transmits power requested by the wireless power receiver 70 and wirelessly transmits power to the power receiver 71. For example, the power transmitter 61 supplies and transmits power in the form of an alternating current (AC) waveform, and converts power in a direct current (DC) waveform into an AC waveform using an inverter while supplying power in the form of a DC waveform and thus also transmits the power in the form of an AC waveform. In addition, the power transmitter 61 is implemented in the form of one of a built-in battery, a power reception interface, or a receiver that receives power from the outside and supplies the power to other components. In an embodiment, the power transmitter 61 transmits an AC waveform to the power receiver 71 in the form of electromagnetic waves.

The communication unit 63 of the wireless power transmitter 60 communicates with the communication unit 73 of the wireless power receiver 70, and for example, performs communication using at least one of Near Field Communication (NFC), infrared communication, visible light communication, etc. The communication unit 63 transmits a signal related to information of the wireless power transmitter 60. The communication unit 63 receives power information requested from the wireless power receiver 70, and for example, the communication unit 63 receives the battery remaining amount, the number of charging times, the usage amount, the battery capacity, the battery percentage of the wireless power receiver 70, etc.

The controller 62 of the wireless power transmitter 60 controls the overall operation of the wireless power transmitter 60. For example, the controller 62 is implemented in the form of one of a CPU, microprocessor, or a mini computer. The controller 62 calculates the power information received by the communication unit 63 and controls whether the power transmitter 61 generates power, the magnitude of the generated power, the power transmission time, etc.

The power receiver 71 wirelessly receives power from the power transmitter 61. The power receiver 71 receives power in an alternating current form and charges the battery 74 through one or more of a rectifier circuit, a regulating circuit, etc. The communication unit 73 of the wireless power receiver 70 transmits requested power information to the communication unit 63, and the controller 72 controls the overall operation of the wireless power receiver 70.

The power receiver 71 includes an overvoltage protection circuit that includes a current source and a resistor are connected in parallel, and the controller 72 controls the overvoltage protection circuit. When the wireless power receiver 70 is repeatedly attached to and detached from the wireless power transmitter 60 over a short time period, the power receiver 71 may receive more than the requested power from the wireless power transmitter 60. An overvoltage can occur in the power receiver 71, and power should be leaked through an overvoltage protection circuit. According to an embodiment of the present inventive concept, the controller 72 alternately connects the resistor and the current source in the overvoltage protection circuit, thereby leaking an amount of power. Therefore, the power receiver 71 is efficiently protected from overvoltage, and power leakage efficiency is maintained by reducing heat generated by a resistor due to power leakage.

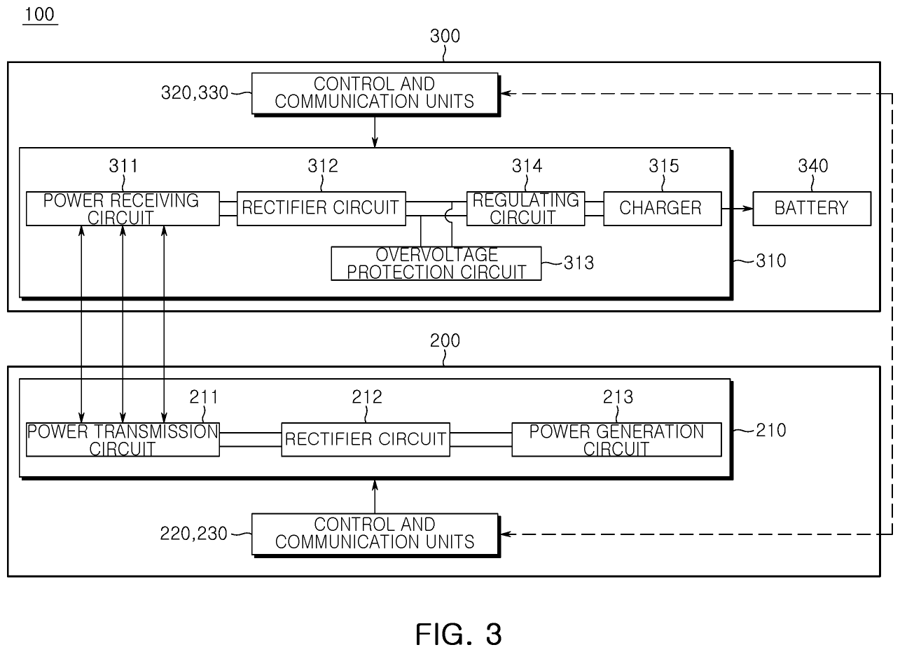

FIG. 3 is a detailed block diagram of a wireless charging system according to an embodiment.

Referring to FIG. 3, in an embodiment, a wireless charging system 100 includes a wireless power transmitter 200 and a wireless power receiver 300. The wireless power transmitter 200 includes a power transmitter 210, and control and communication units 220 and 230, and the power transmitter 210 includes a power transmission circuit 211, a rectifier circuit 212, and a power generation circuit 213. The wireless power receiver 300 includes a power receiver 310, control and communication units 320 and 330, and a battery 330, and the power receiver 310 includes a power receiving circuit 311, a rectifier circuit 312, an overvoltage protection circuit 313, a regulating circuit 314, and a charger 315.

The control and communication units 220 and 230 of the wireless power transmitter 200 performs bidirectional communication with the control and communication units 320 and 330 of the wireless power receiver 300. The communication unit 230 receives power information from the wireless power receiver 300, and the control unit 220 controls the power transmitter 210 based on the received power information.

The wireless power transmitter 200 generates power and wirelessly transmits the power to the wireless power receiver 300. For embodiment, the power generation circuit 213 outputs AC power that has a voltage and frequency specified for the wireless power receiver 300. AC power is rectified by the rectifier circuit 212, and, for example, the rectifier circuit 212 outputs rectified power obtained by single-phase full-wave rectification of AC power. The power transmission circuit 211 transmits rectified power to the wireless power receiver 300 by performing impedance matching with the power receiving circuit 311.

The wireless power receiver 300 wirelessly receives power from the wireless power transmitter 200 and outputs an AC voltage. In an embodiment, the power receiving circuit 311 outputs single-phase full-wave rectified power. The rectifier circuit 312 outputs a rectified voltage by rectifying the AC voltage received from the power receiving circuit 311. The regulating circuit 314 outputs a charging voltage that charges the battery using the rectified voltage, and the charging voltage has a preset voltage value for charging a battery 340. The charger 315 charges the battery 340 using the charging voltage. The power receiver 310 and the battery 340 are controlled by the control unit 320.

According to an embodiment, the power receiver 310 includes an overvoltage protection circuit 313 connected in parallel between the rectifier circuit 312 and the regulating circuit 314. The overvoltage protection circuit 313 includes at least one current source and at least one resistor. When the rectified voltage is greater than a level required by the wireless power receiver 300, the overvoltage protection circuit 313 leaks power to protect the power receiver 310. For example, at least one current source and at least one resistor of the overvoltage protection circuit 313 are alternately connected to the circuit. Accordingly, the internal temperature of the power receiver 310 and the resistor can be maintained within a predetermined range. The operating criterion of the overvoltage protection circuit 313 is the rectified voltage or the internal temperature of the power receiver 310.

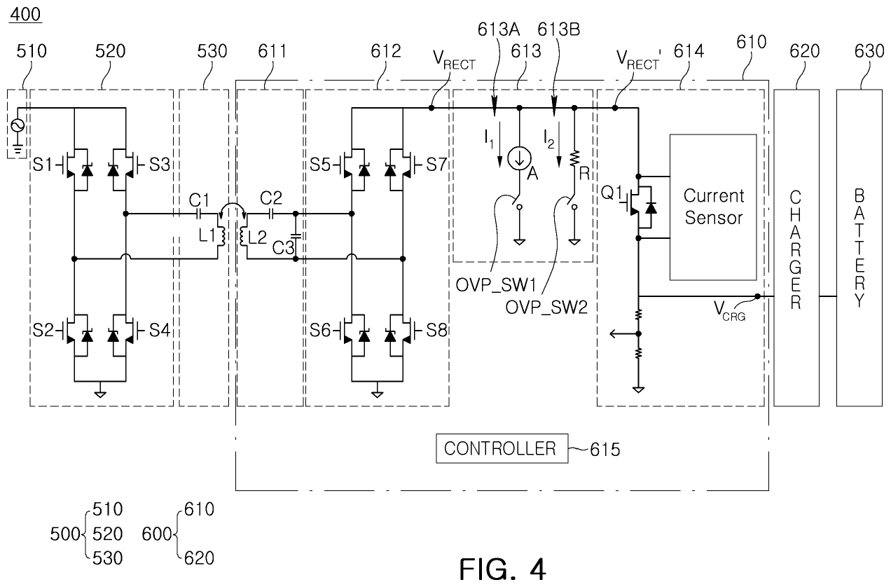

FIG. 4 is a schematic circuit diagram of a wireless charging system according to an embodiment.

Referring to FIG. 4, in an embodiment, a wireless charging system 400 may include a power transmitter 500, a power receiver 600, and a battery 630. The battery 630 may be included in the power receiver 600.

The power transmitter 500 generates power and wirelessly transmits the power to the power receiver 600. The power transmitter 500 includes a power generation circuit 510, a rectifier circuit 520, and a power transmission circuit 530. In an embodiment, the power generation circuit 510 outputs AC power that has a voltage and frequency specified for the wireless power receiver. For example, the power generation circuit 510 includes an AC voltage source. The rectifier circuit 520 rectifies AC power received from the power generation circuit 510. In an embodiment, the rectifier circuit 520 is implemented in the form of a bridge diode (S1-S4), and outputs rectified power obtained by single-phase full-wave rectification of AC power.

The power transmission circuit 530 performs impedance matching and wireless power transmission functions. In an embodiment, the power transmission circuit 530 includes a first capacitor C1 and a first inductor L1, and the first capacitor C1 and the first inductor L1 are connected in series. The controller of the wireless power transmitter adjusts the values of the first capacitor C1 and the first inductor L1 of the power transmission circuit 530 such that power is efficiently transmitted. For example, the power transmission circuit 530 and the power receiving circuit 611 are implemented as resonance circuits that have the same resonance frequency. Accordingly, the power transmission circuit 530 transmits rectified power to the power receiving circuit 611 in the form of electromagnetic waves.

The power receiver 600 charges the battery 630 using the power received from the power transmitter 500. The power receiver 600 includes a wireless charging circuit 610 and a charger 620, and the wireless charging circuit 610 includes a power receiving circuit 611, a rectifier circuit 612, an overvoltage protection circuit 613, and a regulating circuit 614.

The power receiving circuit 611 is impedance matched with the power transmission circuit 530 to wirelessly receive power. The power receiving circuit 611 includes a second inductor L2, a second capacitor C2, and a third capacitor C3. The second inductor L2 and the second capacitor C2 are connected in series, and are connected in parallel with the third capacitor C3. The power received by the power receiving circuit 611 is obtained by single-phase full-wave rectification of AC power in the power transmitter 500, and the power receiving circuit 611 outputs an AC voltage.

The rectifier circuit 612 rectifies the power received by the power receiving circuit 611 into direct current, and the rectifier circuit 612 outputs a rectified voltage V_{RECT}. For example, the rectifier circuit 612 is implemented in the form of bridge diodes S5-S8.

The overvoltage protection circuit 613 performs an overvoltage protection (OVP) operation that prevents overvoltage from occurring in the wireless charging circuit 610. The controller 615 in the wireless power receiver can detect the rectified voltage V_{RECT} that is received from the rectifier circuit 612 and the temperature of the wireless charging circuit 610. The overvoltage protection circuit 613 performs an overvoltage protection operation using the detection results, and the controller 615 controls the overvoltage protection circuit 613.

According to an embodiment, the overvoltage protection circuit 613 is connected in parallel between the rectifier circuit 612 and the regulating circuit 614. The overvoltage protection circuit 613 includes a first overvoltage protection circuit 613A and a second overvoltage protection circuit 613B. The first overvoltage protection circuit 613A includes a current source A and a first switch OVP_SW1 connected in series. The second overvoltage protection circuit 613B includes a resistor R and a second switch OVP_SW2 connected in series. In an embodiment, the resistor R is located outside the area of the overvoltage protection circuit 613, different from that illustrated in FIG. 4.

According to an embodiment, when the first overvoltage protection circuit 613A is turned on, the second overvoltage protection circuit 613B is turned off, and when the first overvoltage protection circuit 613A is turned off, the second overvoltage protection circuit 613B is turned on. For example, when the overvoltage protection circuit 613 satisfies a first operating condition, defined below, the controller 615 turns on the first overvoltage protection circuit 613A. When the overvoltage protection circuit 613 satisfies a second operating condition, defined below, the controller 615 turns off the first overvoltage protection circuit 613A and turns on the second overvoltage protection circuit 613B. For example, the controller 615 turns on only one of the first overvoltage protection circuit 613A or the second overvoltage protection circuit 613B.

The first operating condition refers to when the rectified voltage V_{RECT} is greater than or equal to a first threshold voltage or the temperature of the wireless charging circuit is greater than or equal to a first threshold temperature. The second operating condition refers to when the rectified voltage V_{RECT} is greater than or equal to a second threshold voltage or the temperature of the wireless charging circuit is equal to or greater than a second threshold temperature. The second threshold voltage is greater than the first threshold voltage, and the second threshold temperature is higher than the first threshold temperature. In an embodiment, the controller 615 detects the rectified voltage V_{RECT} and the temperature of the wireless charging circuit. The controller 615 controls the overvoltage protection circuit 613 according to the first and second operating conditions, and the overvoltage protection circuit 613 outputs an overvoltage protection rectified voltage V_{RECT′}.

The first overvoltage protection circuit 613A leaks a first current I1 when turned on, and the second overvoltage protection circuit 613B leaks a second current I2 when turned on. According to an embodiment, the magnitude of the second current I2 is greater than the magnitude of the first current I1, and the amount of power leaking through the second overvoltage protection circuit 613B is greater than an amount of power leaking through the first overvoltage protection circuit 613A. For example, the power supplied to the regulating circuit 614 is less than the power output by the rectifier circuit 612, and, for example, the power supplied to the regulating circuit 614 when the second overvoltage protection circuit 613B is turned on is less than the power supplied to the regulating circuit 614 when the first overvoltage protection circuit 613A is turned on.

The regulating circuit 614 outputs a charging voltage V_{CRG} that charges the battery 630 using the overvoltage protection rectified voltage V_{RECT′}. The regulating circuit 614 includes a AC/DC converter or, as illustrated in FIG. 4, a low dropout circuit. The battery 630 can be stably charged only when the level of the charging voltage V_{CRG} is maintained at a specific value. The regulating circuit 614 converts the overvoltage protection rectified voltage V_{RECT′} into a specific value for charging the battery 630, and outputs the conversion result, the charging voltage V_{CRG}. The charger 620 charges the battery 630 using the charging voltage V_{CRG}.

When the first overvoltage protection circuit 613A is turned on, the temperature of the wireless charging circuit 610 rises, and when the second overvoltage protection circuit 613B is turned on, the temperature of the resistor R increases. According to an embodiment, the first overvoltage protection circuit 613A and the second overvoltage protection circuit 613B are alternately turned on and off to perform an overvoltage protection operation. For example, by repeating turn-on and turn-off, the temperature of the wireless charging circuit 610 and the resistor R can be maintained within a predetermined range. Therefore, damage to the wireless charging circuit 610 due to heat generation can be prevented, and the efficiency of the overvoltage protection operation of the resistor R can be maintained.

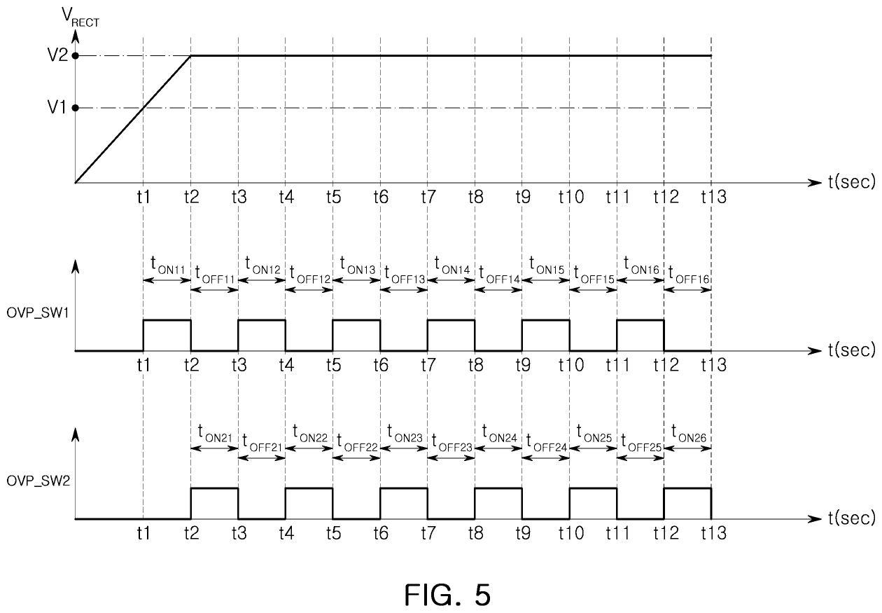

FIG. 5 presents graphs that illustrate a change in rectified voltage and operation of a switch in an overvoltage protection circuit as a function of time, according to an embodiment.

The wireless power receiver includes a wireless charging circuit and a controller, and wirelessly receives power from the wireless power transmitter to charge a built-in battery. The wireless charging circuit includes a power receiving circuit, a rectifier circuit, a regulating circuit, and an overvoltage protection circuit connected in parallel between the rectifier circuit and the regulating circuit. The rectifier circuit outputs a rectified voltage V_{RECT}.

Referring to the first graph of FIG. 5, the graph illustrates a change in rectified voltage V_{RECT} as a function of a time when a wireless power receiver wirelessly receives power, according to an embodiment. When the wireless power receiver starts to receive power, the rectified voltage V_{RECT} increases. The rectified voltage V_{RECT} increases to the first threshold voltage V1 at a first time t1 and increases to the second threshold voltage V2 at a second time t2. After the second time t2, the rectified voltage V_{RECT} is maintained at the second threshold voltage V2.

The overvoltage protection circuit includes a first overvoltage protection circuit that includes a current source and a first switch OVP_SW1, and a second overvoltage protection circuit that includes a resistor R and a second switch OVP_SW2. When the first switch OVP_SW1 is closed, the first overvoltage protection circuit is turned on, and when the second switch OVP_SW2 is closed, the second overvoltage protection circuit is turned on.

Referring to the second graph of FIG. 5 and the third graph of FIG. 5, when the first switch OVP_SW1 is closed, the second switch OVP_SW2 is opened. When the first switch OVP_SW1 is open, the second switch OVP_SW2 is closed. For example, when the first overvoltage protection circuit is turned on, the second overvoltage protection circuit is turned off, and when the first overvoltage protection circuit is turned off, the second overvoltage protection circuit is turned on. Therefore, the turn-on time (t1, t3, . . . ) of the first overvoltage protection circuit and the turn-off time (t1, t3, . . . ) of the second overvoltage protection circuit are the same, and the turn-off time (t2, t4, . . . ) of the first overvoltage protection circuit and the turn-on time (t2, t4, . . . ) of the second overvoltage protection circuit are the same.

Referring to FIG. 5, both the first switch OVP_SW1 and the second switch OVP_SW2 are open until before the first time t1 when the rectified voltage V_{RECT} reaches the first threshold voltage V1. For example, both the first overvoltage protection circuit and the second overvoltage protection circuit are maintained in a turned-off state until before the first time t1.

When the rectified voltage V_{RECT} increases to the first threshold voltage V1, the first switch OVP_SW1 is closed and the first overvoltage protection circuit is turned on. In an embodiment illustrated in FIG. 5, the first overvoltage protection circuit is turned on at the first time t1. On the other hand, since the second switch OVP_SW2 is still open, the second overvoltage protection circuit remains turned off for a while after the first time t1.

During the time when the rectified voltage V_{RECT} is greater than or equal to the first threshold voltage V1 and less than the second threshold voltage V2, the first overvoltage protection circuit is maintained in a turned-on state, and the second overvoltage protection circuit is maintained in a turned-off state. For example, during the first turn-on maintaining time t_{ON11} of the first overvoltage protection circuit, the second overvoltage protection circuit is turned off, and the rectified voltage V_{RECT} increases.

At a second time t2 when the rectified voltage V_{RECT} reaches the second threshold voltage V2, the first switch OVP_SW1 is opened and the first overvoltage protection circuit is changed to a turn-off state. In addition, the second switch OVP_SW2 is closed at the second time t2, and the second overvoltage protection circuit changes to a turn-on state. For example, at the second time t2, the first overvoltage protection circuit is turned off and the second overvoltage protection circuit is turned on.

After the second time t2, the first switch OVP_SW1 and the second switch OVP_SW2 are alternately opened and closed. For example, the first overvoltage protection circuit and the second overvoltage protection circuit repeat turn-on and turn-off operations. Therefore, the rectified voltage V_{RECT} is limited not to exceed the second threshold voltage V2.

For example, at the third time t3, the first switch OVP_SW1 is closed, and the first overvoltage protection circuit changes to a turn-on state. In addition, at the third time t3, the second switch OVP_SW2 is opened again, and the second overvoltage protection circuit changes to a turned-off state. For example, at the third time t3, the first overvoltage protection circuit is turned on and the second overvoltage protection circuit is turned off.

As the first and second overvoltage protection circuits are repeatedly turned on and off, the wireless charging circuit and the resistance are adjusted to not exceed a predetermined temperature. Therefore, damage to the wireless charging circuit and resistor due to a high temperature can be prevented.

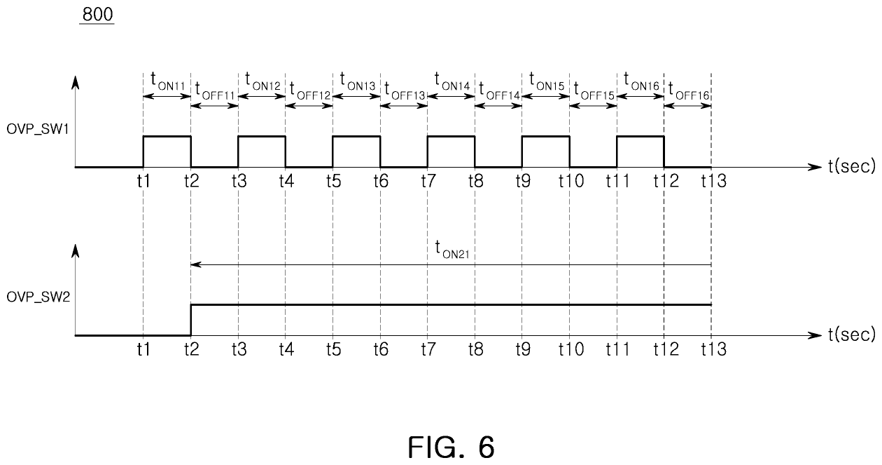

FIGS. 6 to 12 are graphs that illustrate an operation of a switch in an overvoltage protection circuit as a function of time, according to embodiments.

The overvoltage protection circuit includes a first overvoltage protection circuit that includes a current source and a first switch OVP_SW1, and a second overvoltage protection circuit that includes a resistor and a second switch OVP_SW2. At least one of the period and time during which the first switch OVP_SW1 and the second switch OVP_SW2 are opened can be set differently.

For example, referring to FIGS. 6 to 12, the first overvoltage protection circuit is turned on before the second overvoltage protection circuit, and at least one of the first overvoltage protection circuit or the second overvoltage protection circuit is repeatedly turned on and turned off. For example, when compared to an embodiment illustrated in FIG. 5, in embodiments illustrated in FIGS. 6 to 12, the turn-on time of the first overvoltage protection circuit and the turn-off time of the second overvoltage protection circuit do not coincide, and the turn-off time of the first overvoltage protection circuit and the turn-on time of the second overvoltage protection circuit do not coincide.

Referring to FIGS. 6 to 10, the first switch OVP_SW1 repeats opening and closing operations at regular intervals. For example, the first overvoltage protection circuit is repeatedly turned on and turned off. A detailed operation of the first switch OVP_SW1 illustrated in FIGS. 6 to 10 is substantially similar to the operation of the first switch OVP_SW1 illustrated in FIG. 5. For example, the turn-on holding times (t_{ON11}, t_{ON12}, . . . ) of the first overvoltage protection circuit are equal to the turn-off holding times (t_{OFF11}, t_{OFF12}, . . . ) of the first overvoltage protection circuit.

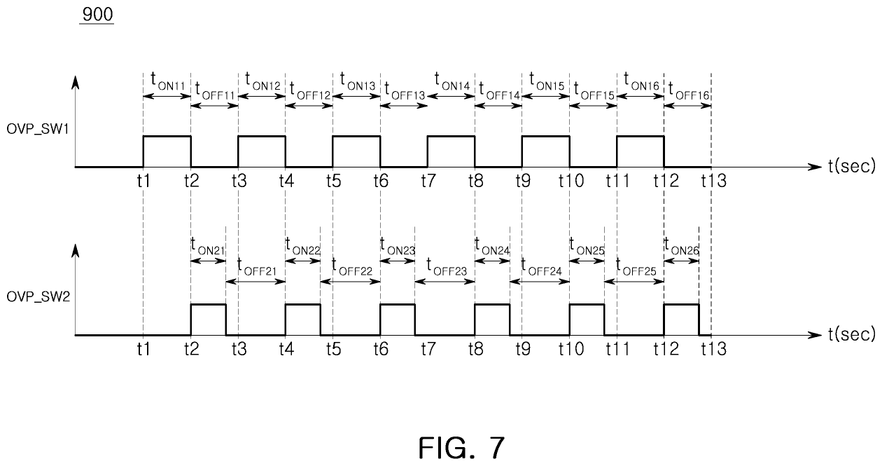

Referring to FIGS. 6 and 7, at a first time t1, the first switch OVP_SW1 is closed before the second switch OVP_SW2. At the second time t2, the second switch OVP_SW2 is closed and the first switch OVP_SW1 is opened. For example, at the second time t2, the second overvoltage protection circuit is turned on and the first overvoltage protection circuit is turned off.

According to an embodiment illustrated in FIG. 6, the second switch OVP_SW2 is maintained a closed state after the second time t2. The first turn-on holding time t_{ON21} of the second overvoltage protection circuit is longer than the total turn-on holding times, (the sum of t_{ON11}, t_{ON12}, . . . ) of the first overvoltage protection circuit. For example, the total turn-off holding time of the second overvoltage protection circuit is shorter than the total turn-off holding time (sum of t_{OFF11}, t_{OFF12}, . . . ) of the first overvoltage protection circuit. In an embodiment illustrated in FIG. 6, since the second switch OVP_SW2 remains closed after the second time t2, the wireless charging circuit is strongly protected due to power leaking through the second overvoltage protection circuit. However, compared to an embodiment illustrated in FIG. 5, the amount of heat generated by the resistor in the second overvoltage protection circuit illustrated in FIG. 6 is greater than that of an embodiment illustrated in FIG. 5, and thus the power leakage efficiency is relatively low.

According to an embodiment illustrated in FIG. 7, unlike an embodiment illustrated in FIG. 6, the second switch OVP_SW2 repeats an opening and closing operation at regular intervals. For example, the second overvoltage protection circuit repeats turn-on and turn-off operations. For example, the turn-on holding times (t_{ON21}, t_{ON22}, . . . ) of the second overvoltage protection circuit are shorter than the turn-off holding times (t_{OFF21}, t_{OFF22}, . . . ) of the second overvoltage protection circuit.

In an embodiment illustrated in FIG. 7, the turn-off time of the second overvoltage protection circuit does not coincide with the turn-on time (t3, t5, . . . ) of the first overvoltage protection circuit. For example, the total turn-off holding time (sum of t_{OFF21}, t_{OFF22}, . . . ) of the second overvoltage protection circuit is longer than the total turn-off holding time (sum of t_{OFF11}, t_{OFF12}, . . . ) of the first overvoltage protection circuit. In addition, at least a portion of the turn-off holding time (t_{OFF21}, t_{OFF22}, . . . ) of the second overvoltage protection circuit overlaps with the turn-off holding time (t_{OFF11}, t_{OFF12}, . . . ) of the first overvoltage protection circuit. For example, a portion of the first turn-off holding time t_{OFF21} of the second overvoltage protection circuit overlaps a portion of the first turn-off holding time t_{OFF11} of the first overvoltage protection circuit. By overlapping the turn-off holding time of the first and second overvoltage protection circuits, heat generation of the wireless charging circuit and the resistor can be more efficiently reduced, thereby increasing the efficiency of overvoltage protection.

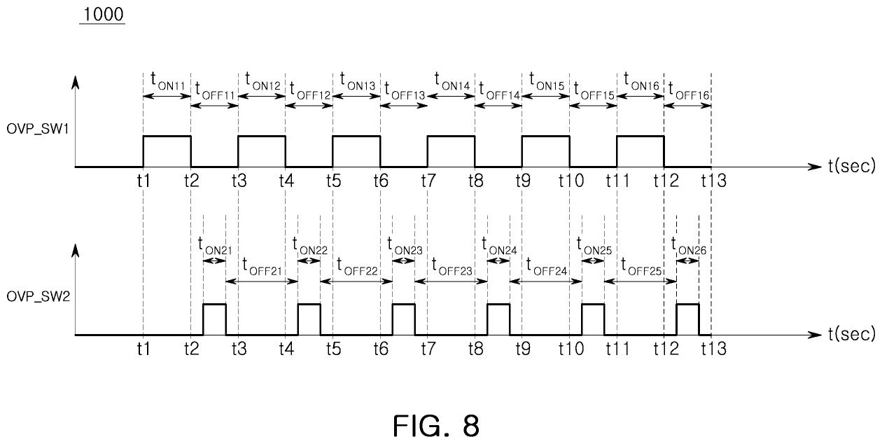

Referring to FIGS. 8 to 10, the first switch OVP_SW1 is closed at a first time t1 before the second switch OVP_SW2. However, unlike embodiments illustrated in FIGS. 6 and 7, the closing time of the second switch OVP_SW2 and the opening time of the first switch OVP_SW1 do not coincide. For example, the turn-on time of the first overvoltage protection circuit and the turn-off time of the second overvoltage protection circuit do not coincide, and the turn-off time of the first overvoltage protection circuit and the turn-on time of the second overvoltage protection circuit do not coincide.

According to an embodiment illustrated in FIG. 8, turn-on holding times (t_{ON11}, t_{ON12}, . . . ) of the first overvoltage protection circuit are longer than the turn-on holding times (t_{ON21}, t_{ON22}, . . . ) of the second overvoltage protection circuit, and are shorter than the turn-off holding times (t_{OFF21}, t_{OFF22}, . . . ) of the second overvoltage protection circuit. The turn-off holding time of the second overvoltage protection circuit overlaps each of adjacent turn-off holding time of the first overvoltage protection circuit. For example, a portion of the first turn-off holding time t_{OFF21} of the second overvoltage protection circuit overlaps the first turn-off holding time t_{OFF11} and the second turn-off holding time t_{OFF12} of the first overvoltage protection circuit. Compared to the second switch OVP_SW2 illustrated in FIG. 7, since the turn-on holding time t_{ON21}, t_{ON22}, . . . , is shortened, the amount of current leakage through the second overvoltage protection circuit is reduced, but the performance of the second overvoltage protection circuit is protected by effectively lowering the temperature of the resistor.

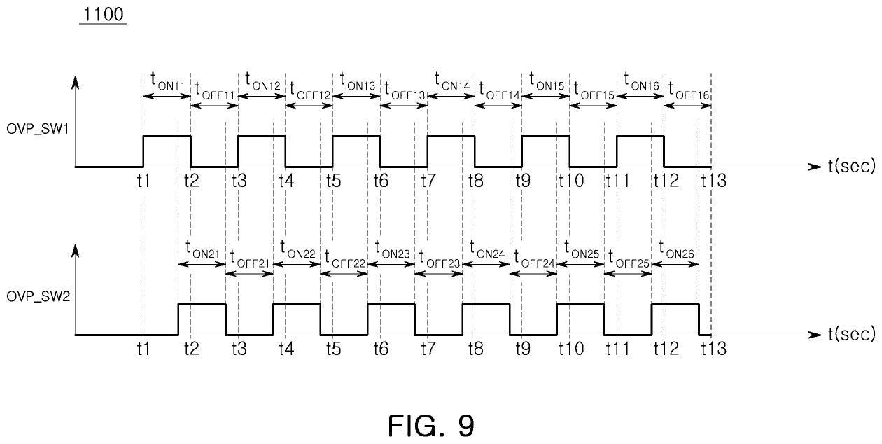

According to an embodiment illustrated in FIG. 9, the second switch OVP_SW2 is not closed at the second time t2 and the second switch OVP_SW2 is not opened at the third time t3. For example, at least a portion of the turn-on holding time (t_{ON21}, t_{ON22}, . . . ) of the second overvoltage protection circuit overlaps the turn-on holding time (t_{ON11}, t_{ON12}, . . . ) of the first overvoltage protection circuit. In addition, at least a portion of the turn-off holding time (t_{OFF21}, t_{OFF22}, . . . ) of the second overvoltage protection circuit overlaps the turn-off holding time (t_{OFF11}, t_{OFF12}, . . . ) of the first overvoltage protection circuit. In the time period where the turn-on holding time (t_{ON11}, t_{ON12}, . . . ) of the first overvoltage protection circuit overlaps a portion of the turn-on holding time (t_{ON21}, t_{ON22}, . . . ) of the second overvoltage protection circuit, since both the first and second overvoltage protection circuits perform an overvoltage protection operation, the wireless charging circuit is more efficiently protected from overvoltage than an embodiment illustrated in FIG. 7.

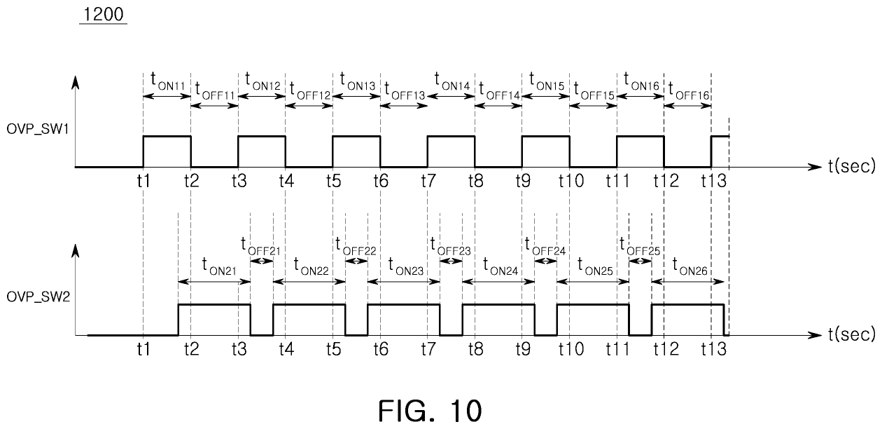

According to the embodiment illustrated in FIG. 10, the second switch OVP_SW2 is not closed at the second time t2 and the second switch OVP_SW2 is not opened at the third time t3. For example, at least a portion of the turn-on holding time of the second overvoltage protection circuit overlaps each adjacent turn-on holding time of the first overvoltage protection circuit. For example, a first portion of the first turn-on holding time t_{ON21} of the second overvoltage protection circuit overlaps the first turn-on holding time t_{ON11} and a second portion of the first turn-on holding time t_{ON21} of the second overvoltage protection circuit overlaps the second turn-on holding time t_{ON12} of the first overvoltage protection circuit. Compared to the second switch OVP_SW2 illustrated in FIG. 9, the turn-on holding times t_{ON21}, t_{ON22}, . . . , of the second switch OVP_SW2 increase, and thus an amount of current leakage through the second overvoltage protection circuit increases. Therefore, the wireless charging circuit is more efficiently protected from overvoltage than an embodiment illustrated in FIG. 9.

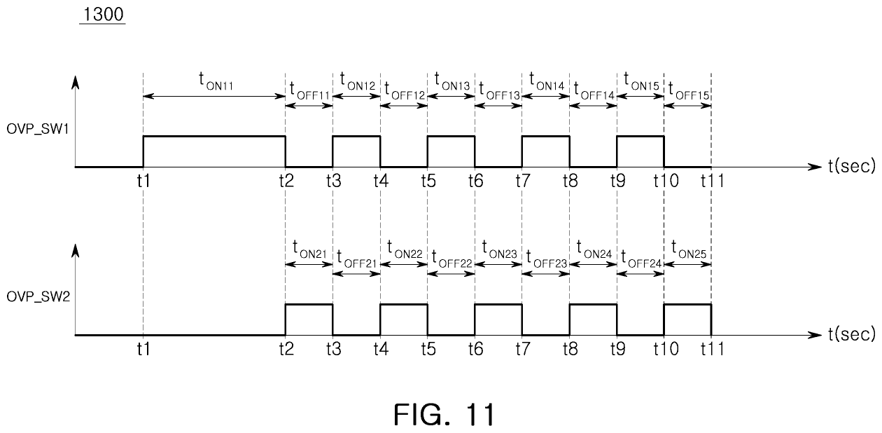

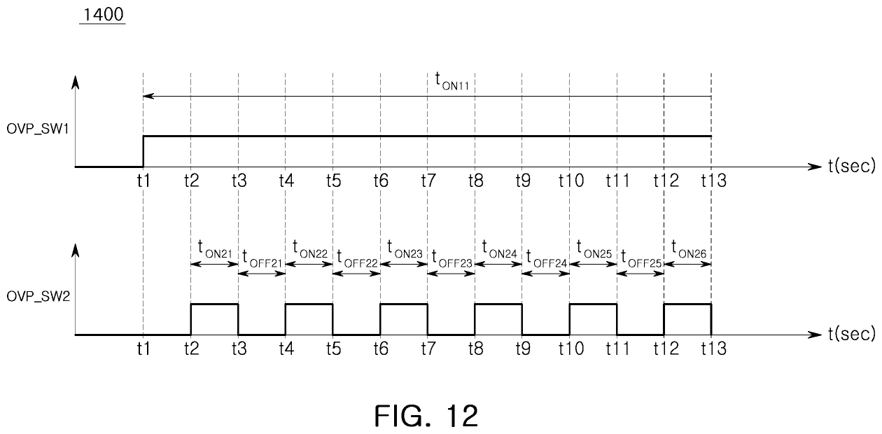

According to embodiments illustrated in FIGS. 11 and 12, the second switch OVP_SW2 repeats an opening and closing operation at regular intervals. For example, the second overvoltage protection circuit repeats turn-on and turn-off operations. A detailed operation of the second switch OVP_SW2 illustrated in FIGS. 11 and 12 is substantially similar to an operation of the second switch OVP_SW2 illustrated in FIG. 5, and a repeated description thereof may be summarized or omitted.

The first turn-on holding time t_{ON11} of the first overvoltage protection circuit of FIG. 11 is longer than the first turn-on holding time t_{ON11} of the first overvoltage protection circuit of FIG. 5. The first turn-on maintaining time t_{ON11} varies according to the magnitude of the current source in the first overvoltage protection circuit. For example, the longer is the first turn-on holding time of the first overvoltage protection circuit, the smaller is the current emitted by the current source.

According to an embodiment illustrated in FIG. 12, after the first switch OVP_SW1 is closed at the first time t1, the closed state is maintained. The first turn-on holding time (t_{ON11}) of the first overvoltage protection circuit is longer than the total turn-on holding time (sum of t_{ON21}, t_{ON22}, . . . ) of the second overvoltage protection circuit. For example, the total turn-off holding time of the first overvoltage protection circuit is shorter than the total turn-off holding time (sum of t_{OFF21}, t_{OFF22}, . . . ) of the second overvoltage protection circuit. In an embodiment illustrated in FIG. 12, since the first switch OVP_SW1 is not repeatedly opened and closed, the wireless charging circuit is protected due to power leaking through the first overvoltage protection circuit. However, the amount of heat generated by the current source in the first overvoltage protection circuit illustrated in FIG. 12 is greater than that of an embodiment of FIG. 5.

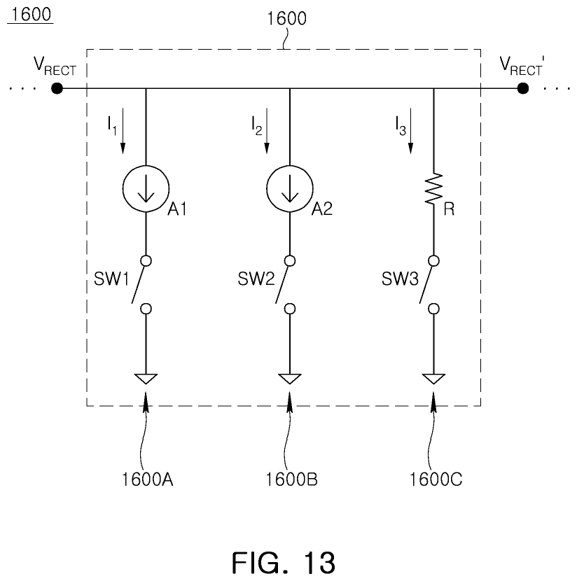

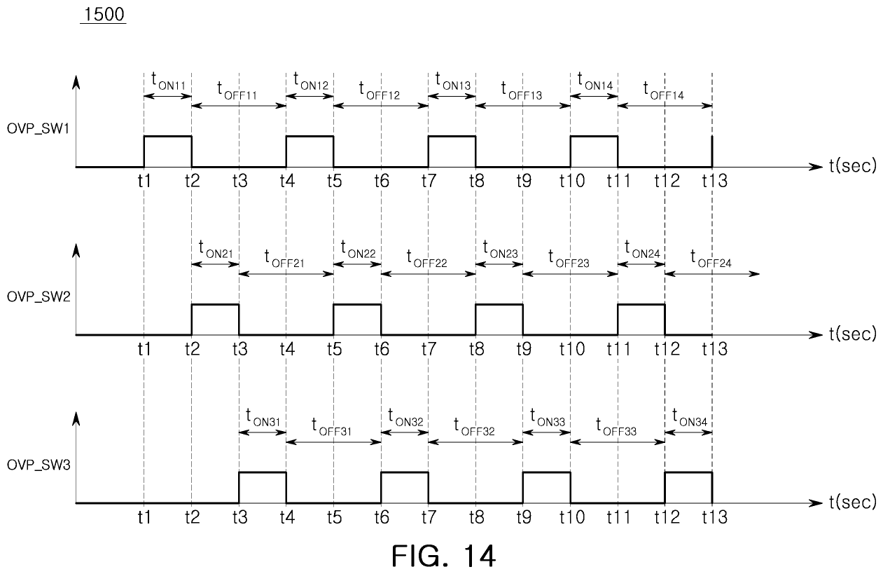

FIG. 13 schematically illustrates a circuit diagram of an overvoltage protection circuit according to an embodiment. FIG. 14 is a graph that illustrates an operation of switches in the overvoltage protection circuit of FIG. 13 as a function of time, according to an embodiment.

The wireless charging circuit includes a power receiving circuit, a rectifier circuit, a regulating circuit, a controller, and an overvoltage protection circuit. The circuit diagram of an embodiment illustrated in FIG. 13 simply represents a circuit diagram of an overvoltage protection circuit 1600, and FIG. 13 omits the configuration of the wireless charging circuit. Compared to a wireless charging circuit 610 of FIG. 4, there is a difference in the configuration of the overvoltage protection circuit.

The overvoltage protection circuit 1600 is connected in parallel between the rectifier circuit and the regulating circuit, and the rectified voltage V_{RECT} is input to the overvoltage protection circuit 1600, which outputs an overvoltage protection rectified voltage V_{RECT′}. The overvoltage protection circuit 1600 includes at least one current source and/or at least one resistor, and the current source and/or resistor are connected in parallel. In an embodiment illustrated in FIG. 13, the overvoltage protection circuit 1600 includes a first overvoltage protection circuit 1600A that includes a first current source A1 and a first switch SW1, a second overvoltage protection circuit 1600B that includes a second current source A2 and a second switch SW2, and a third overvoltage protection circuit 1600C that includes a resistor R and a third switch SW3. For example, the first current I1 leaked by the first overvoltage protection circuit 1600A may be the same as or different from the second current I2 leaked by the second overvoltage protection circuit 1600B. The configuration of the overvoltage protection circuit 1600 is not necessarily limited thereto.

The turning on of the overvoltage protection circuits 1600A, 1600B, and 1600C varies depending on the operating conditions satisfied by the overvoltage protection circuit 1600. For example, in an embodiment, the controller alternately turns on only one of the first to third overvoltage protection circuits 1600A, 1600B, and 1600C at a time, but embodiments of the present inventive concept are not necessarily limited thereto.

According to an embodiment illustrated in FIG. 14, when the first operating condition of the overvoltage protection circuit 1600 is satisfied, the first switch SW1 is closed. When the second operating condition of the overvoltage protection circuit 1600 is satisfied, the first switch SW1 is opened and the second switch SW2 is closed. When a third operating condition of the overvoltage protection circuit 1600 is satisfied, the open state of the first switch SW1 is maintained, the second switch SW2 is opened, and the third switch SW3 is closed. Then, one of the first to third switches SW1 to SW3 is alternately closed.

For example, when the overvoltage protection circuit 1600 satisfies the first operating condition, the first overvoltage protection circuit 1600A is turned on. When the overvoltage protection circuit 1600 satisfies the second operating condition, the first overvoltage protection circuit 1600A is turned off and the second overvoltage protection circuit 1600B is turned on. When the overvoltage protection circuit 1600 satisfies the third operating condition, the second overvoltage protection circuit 1600B is turned off and the third overvoltage protection circuit 1600C is turned on. For example, only one of the first to third overvoltage protection circuits 1600A, 1600B, and 1600C is alternately turned on.

The first operating condition refers to when the rectified voltage VRECT is greater than or equal to a first threshold voltage or the temperature of the wireless charging circuit is greater than or equal to a first threshold temperature. The second operating condition refers to when the rectified voltage VRECT is greater than or equal to a second threshold voltage or the temperature of the wireless charging circuit is equal to or greater than a second threshold temperature. The third operating condition refers to when the rectified voltage VRECT is greater than or equal to a third threshold voltage or the temperature of the wireless charging circuit is equal to or greater than a third threshold temperature. The third threshold voltage is greater than the first threshold voltage and the second threshold voltage, and the third threshold temperature is higher than the first threshold temperature and the third threshold temperature.

Compared to the overvoltage protection circuit 613 illustrated in FIG. 4, the overvoltage protection circuit 1600 illustrated in FIG. 13 further includes an additional overvoltage protection circuit that includes a current source. Accordingly, the power leakage efficiency of FIG. 13 is higher than the power leakage efficiency of FIG. 4. In addition, the turn-off holding time of each of the overvoltage protection circuits 1600A, 1600B, and 1600C illustrated in FIG. 14 is longer than the turn-off holding time of each of the overvoltage protection circuits 613A and 613B of FIG. 4. For example, the wireless charging circuit and/or the resistor R can be efficiently protected from a high temperature by ensuring a sufficient time to lower the temperature of the resistor R and/or the internal temperature of the wireless charging circuit of FIG. 13.

Operations of the switches SW1-3 in the overvoltage protection circuit 1600 illustrated in FIG. 13 are not necessarily limited to those of FIG. 14, and at least one of the switch operations illustrated in FIGS. 6 to 12 may be applied.

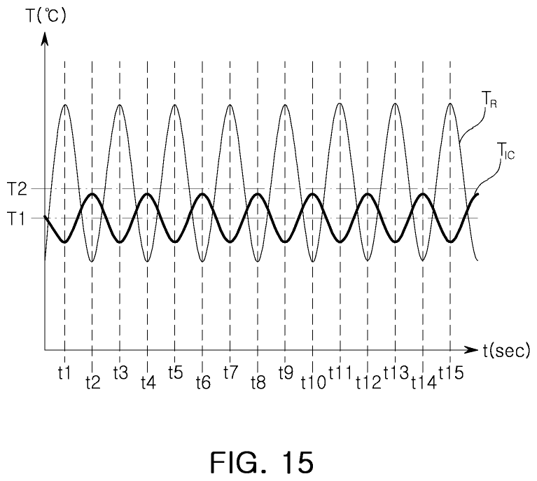

FIG. 15 is a graph of temperature changes of a wireless charging circuit and an resistor as a function of time while an overvoltage protection circuit operates, according to an embodiment.

The wireless charging circuit includes a power receiving circuit, a rectifier circuit, a regulating circuit, a controller, and an overvoltage protection circuit. The overvoltage protection circuit includes a first overvoltage protection circuit that includes a current source and a second overvoltage protection circuit that includes a resistor. Even when an overvoltage occurs in the power receiving circuit, the battery can be charged with a constant voltage by leaking power in the overvoltage protection circuit.

When the overvoltage protection circuit leaks power, the temperature of the wireless charging circuit or the temperature of the resistor increases. When the temperature of the wireless charging circuit becomes high, damage can occur to the wireless charging circuit. When the temperature of the resistor increases, the efficiency of power leakage through the resistor decreases. In an embodiment of the present inventive concept, by alternately turning on only one of the first overvoltage protection circuit or the second overvoltage protection circuit, the temperature (T_{IC}) of the wireless charging circuit and the temperature (T_{R}) of the resistor can be maintained within a predetermined range. In an embodiment, the temperature T_{IC} of the wireless charging circuit is maintained within a first predetermined range based on the first temperature T1, and the temperature T_{R} of the resistor is maintained within a second predetermined range based on the second temperature T2. For example, the second temperature T2 is higher than the first temperature T1, but is not necessarily limited thereto.

In an embodiment illustrated in FIG. 15, when the first overvoltage protection circuit is turned on, the temperature T_{IC} of the wireless charging circuit increases, and when the first overvoltage protection circuit is turned off, the temperature T_{IC} of the wireless charging circuit decreases. When the second overvoltage protection circuit is turned on, the temperature T_{R} of the resistor increases, and when the second overvoltage protection circuit is turned off, the temperature T_{R} of the resistor decreases. As the first and second overvoltage protection circuits are alternately turned on and off, the temperature T_{R} of the resistor is lowest when the temperature T_{IC} of the wireless charging circuit is highest, and when the temperature T_{IC} of the wireless charging circuit is lowest, the temperature T_{R} of the resistor is highest.

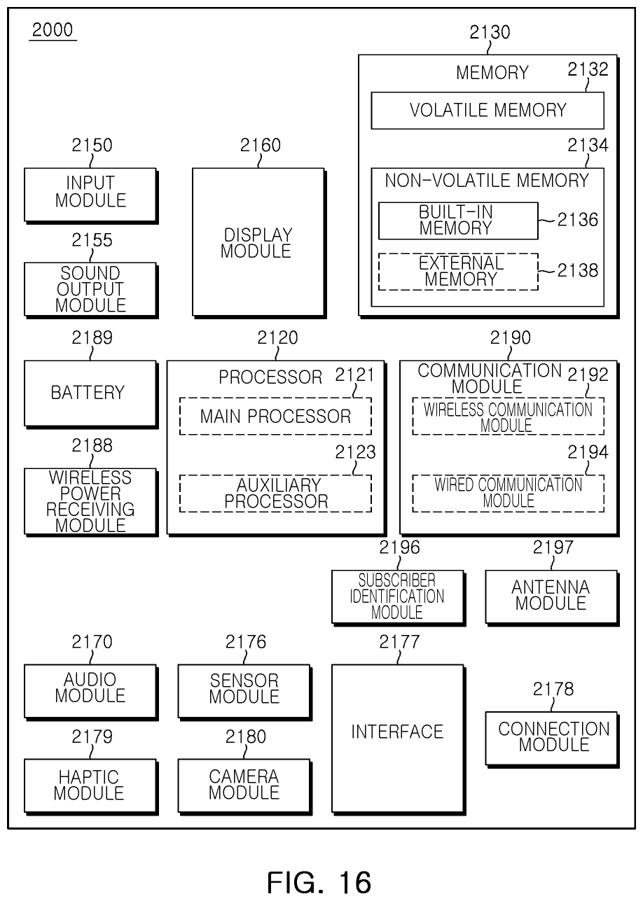

FIG. 16 is a block diagram of an electronic device according to an embodiment.

According to an embodiment illustrated in FIG. 16, an electronic device 2000 include a processor 2120, a memory 2130, an input module 2150, a sensor module 2176, an interface 2177, a connection terminal 2178, a wireless power receiving module 2188, a battery 2189, etc. In addition, the electronic device 2000 includes a display module 2160, a sound output module 2155, a communication module 2190 that includes a wireless communication module 2192 and a wired communication module 2194, an audio module 2170, a haptic module 2179, a camera module 2180m an antenna module 2197 and a subscriber identification module 2196.

The processor 2120 executes software that controls at least one of the components of the electronic device 2000 that are connected to the processor 2120, and also performs various data processing operations or calculations. According to an embodiment, the processor 2120 stores in a volatile memory 2132 commands or data received from other components, processes the commands or data stored in the volatile memory 2132, and stores the resulting data in a non-volatile memory 2134. According to an embodiment, the processor 2120 includes a main processor 2121 such as a central processing unit, etc., and an auxiliary processor 2123, such as a graphics processing unit and/or a communication processor, etc. The auxiliary processor 2123 uses less power than the main processor 2121.

The memory 2130 stores data used by components of the electronic device 2000. The memory 2130 includes the volatile memory 2132 and/or the non-volatile memory 2134. The non-volatile memory 2134 includes built-in memory 2136 and an external memory 2138. The input module 2150 receives commands or data from outside the electronic device 2000 to be used by the electronic device 2000. For example, the input module 2150 includes one or more of a microphone, a mouse, a keyboard, keys, or a digital pen.

The sensor module 2176 detects an operating state such as power or temperature of the electronic device 2000, or an external environmental state, and generates an electrical signal or data value that corresponds to the sensed state. The interface 2177 supports one or more specified communication protocols that can be used to directly or wirelessly connect the electronic device 2000 to an external electronic device. The connection terminal 2178 includes a connector through which the electronic device 2000 can be physically connected to an external electronic device.

The wireless power receiving module 2188 manages power wirelessly supplied to the electronic device 2000. According to an embodiment, the wireless power receiving module is implemented as a portion of a power management integrated circuit (PMIC). According to an embodiment, the wireless power receiving module 2188 includes a wireless power receiver, a controller, and a communication unit, and detailed embodiments are similar to those described with reference to FIGS. 2 and 3.

The battery 2189 supplies power to at least one component of the electronic device 2000, and according to an embodiment, can be wirelessly charged by the wireless power receiving module 2188. The battery 2189 includes a rechargeable secondary cell or fuel cell.

In an embodiment, the wireless power receiving module 2188 includes an overvoltage protection circuit. The overvoltage protection circuit includes at least one current source and/or at least one resistor that are connected in parallel. At least one current source and/or at least one resistor are alternately connected to the wireless charging circuit at regular intervals. Accordingly, by maintaining the temperature of the wireless power receiving module 2188 within a predetermined range, damage to the wireless power receiving module 2188, which can occur due to high temperatures, can be prevented.

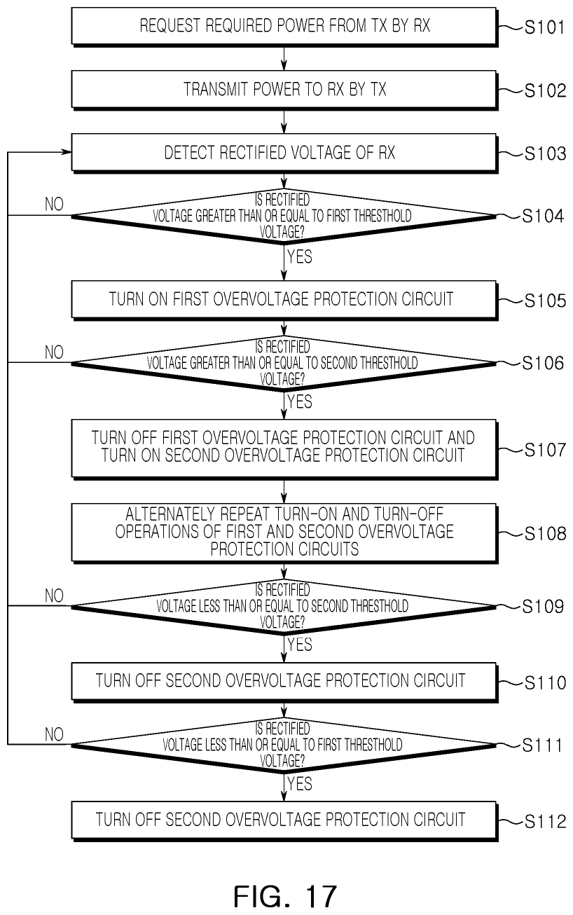

FIG. 17 is a flowchart of an operation process of an overvoltage protection circuit according to an embodiment.

In an embodiment, a wireless charging system includes a wireless power transmitter and a wireless power receiver. A wireless power transmitter includes a power transmitter (Tx), a controller, and a communication unit. The wireless power transmitter transmits power to the wireless power receiver in an alternating current form through the power transmitter Tx. The wireless power receiver includes a power receiver (Rx), a controller, a communication unit, and a battery. The wireless power receiver receives AC power from the wireless power transmitter through the power receiver Rx and converts the AC power into DC power that can charge the battery.

According to the embodiment illustrated in FIG. 17, the power receiver Rx requests power from the power transmitter Tx (S101), and the power receiver Rx also transmits information about the power needed for charging the battery through the communication unit. The power transmitter Tx uses the received information to generate AC power and transmits the generated AC power to the power receiver Rx (S102). Power is transmitted in the form of electromagnetic waves.

The power receiver Rx rectifies the received AC power and discharges the rectified voltage to the overvoltage protection circuit. The controller in the wireless power receiver detects the rectified voltage (S103) and compares the detected voltage with a first threshold voltage (S104). If the rectified voltage is not equal to or greater than the first threshold voltage, the rectified voltage is detected again (S103). When the rectified voltage is equal to or greater than the first threshold voltage, the first overvoltage protection circuit is turned on (S105).

The controller again detects the rectified voltage and compares the detected voltage with a second threshold voltage (S106). If the rectified voltage is not equal to or greater than the second threshold voltage, the rectified voltage is detected again (S103). When the rectified voltage is equal to or greater than the second threshold voltage, the first overvoltage protection circuit is turned off and the second overvoltage protection circuit is turned on (S107). Thereafter, the first and second overvoltage protection circuits repeat turn-on and turn-off operations at regular intervals (S108).

The controller again detects the rectified voltage and compares the detected voltage with the second threshold voltage (S109). If the rectified voltage is not equal to or less than the second threshold voltage, the rectified voltage is detected again (S103). When the rectified voltage is less than or equal to the second threshold voltage, the second overvoltage protection circuit is turned off (S110).

Thereafter, the rectified voltage is compared with the first threshold voltage (S111). If the rectified voltage is not equal to or less than the first threshold voltage, the rectified voltage may be detected again (S103). When the rectified voltage is less than or equal to the first threshold voltage, the first overvoltage protection circuit is turned off (S112).

The wireless charging circuit is more accurately protected from overvoltage by operating the first and second overvoltage protection circuits based on the rectified voltage. In addition, as the first and second overvoltage protection circuits are alternately turned on and off, the temperature of the wireless charging circuit and the resistor is maintained within a predetermined range, and overvoltage protection is also effectively performed.

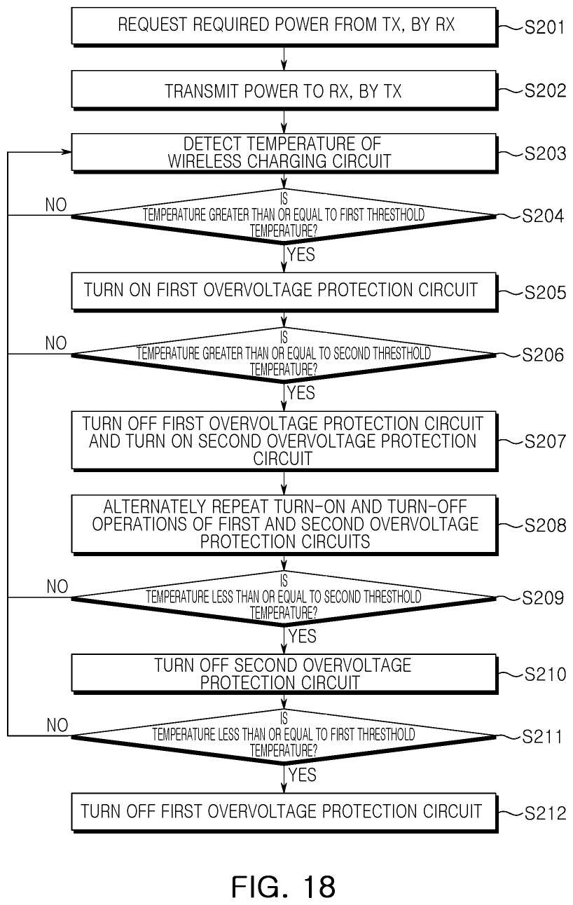

FIG. 18 is a flowchart of an operation process of an overvoltage protection circuit according to an embodiment.

FIG. 17 illustrates a case in which the operating standard of the overvoltage protection circuit is a rectified voltage, and FIG. 18 differs therefrom in that the operating criterion of the overvoltage protection circuit is the temperature of the wireless charging circuit. The detailed embodiment of FIG. 18 is substantially similar to that described in FIG. 17.

According to the embodiment illustrated in FIG. 18, the power receiver Rx requests power from the power transmitter Tx (S201), and the power transmitter (Tx) generates AC power and transmits the power to the power receiver (Rx) (S202).

The power receiver Rx rectifies the received alternating-type power and discharges the rectified voltage to the overvoltage protection circuit. The controller in the wireless power receiver detects the temperature of the wireless charging circuit (S203) and compares the detected temperature with a first threshold temperature (S204). If the temperature of the wireless charging circuit is not equal to or higher than the first threshold temperature, the temperature of the wireless charging circuit is detected again (S203). When the temperature of the wireless charging circuit is equal to or higher than the first threshold temperature, the first overvoltage protection circuit is turned on (S205).

The controller again detects the temperature of the wireless charging circuit and compares the detected temperature with a second threshold temperature (S206). If the temperature of the wireless charging circuit is not equal to or higher than the second threshold temperature, the temperature of the wireless charging circuit is detected again (S203). When the temperature of the wireless charging circuit is equal to or higher than the second critical temperature, the first overvoltage protection circuit is turned off and the second overvoltage protection circuit is turned on (S207). Thereafter, the first and second overvoltage protection circuits repeat turn-on and turn-off operations at regular intervals (S208).

The controller detects the temperature of the wireless charging circuit and compares the detected temperature with the second threshold temperature again (S209). When the temperature of the wireless charging circuit is not equal to or less than the second threshold temperature, the temperature of the wireless charging circuit is detected again (S203). When the temperature of the wireless charging circuit is less than or equal to the second threshold temperature, the second overvoltage protection circuit is turned off (S210).

The temperature of the wireless charging circuit is compared with the first threshold temperature (S211). If the temperature of the wireless charging circuit is not equal to or less than the first threshold temperature, the temperature of the wireless charging circuit is detected again (S203). When the temperature of the wireless charging circuit is less than or equal to the first threshold temperature, the first overvoltage protection circuit is turned off (S212).

A wireless charging circuit can be efficiently protected from high temperatures by operating the first and second overvoltage protection circuits based on the temperature of the wireless charging circuit. In addition, since the first and second overvoltage protection circuits are alternately turned on and off, heat generated by the wireless charging circuit and the resistor is maintained within a predetermined range, and overvoltage protection also efficiently operates.

As set forth above, according to an embodiment, when an overvoltage occurs in a wireless charging circuit, power loss is efficiently generated by turning on the overvoltage protection circuit. The wireless charging circuit includes a first overvoltage protection circuit and a second overvoltage protection circuit, and by repeating turn-on and turn-off operations for at least one of the first overvoltage protection circuit or the second overvoltage protection circuit, circuit damage due to heat can be prevented.

While embodiments have been illustrated and described above, it will be apparent to those skilled in the art that modifications and variations can be made without departing from the scope of embodiments of the present inventive concept as defined by the appended claims.

What is claimed is:

1. A wireless charging circuit, comprising:
a power receiving circuit that wirelessly receiving power and includes an inductor a capacitor;
a rectifier circuit that rectifies an alternating current voltage received from the power receiving circuit and outputs a rectified voltage;
a regulating circuit that outputs a charging voltage that charges a battery using the rectified voltage;
an overvoltage protection circuit connected in parallel between the rectifier circuit and the regulating circuit; and
a controller that detects the rectified voltage and controls the overvoltage protection circuit,
wherein the overvoltage protection circuit includes a first overvoltage protection circuit and a second overvoltage protection circuit, the second overvoltage protection circuit is turned off when the first overvoltage protection circuit is turned on, and the second overvoltage protection circuit is turned on when the first overvoltage protection circuit is turned off.

2. The wireless charging circuit of claim 1, wherein power supplied to the regulating circuit is less than power received from the rectifier circuit.

3. The wireless charging circuit of claim 1, wherein the first overvoltage protection circuit includes a current source, and the second overvoltage protection circuit includes a resistor.

4. The wireless charging circuit of claim 3, wherein power supplied to the regulating circuit when the second overvoltage protection circuit is turned on is less than power supplied to the regulating circuit when the first overvoltage protection circuit is turned on.

5. The wireless charging circuit of claim 1, wherein the controller turns on the first overvoltage protection circuit when the rectified voltage is equal to or greater than a first threshold voltage, and turns on the second overvoltage protection circuit when the rectified voltage is greater than or equal to a second threshold voltage.

6. The wireless charging circuit of claim 5, wherein the second threshold voltage is greater than the first threshold voltage.

7. The wireless charging circuit of claim 5, wherein a turn-on holding time of the first overvoltage protection circuit is equal to a turn-on holding time of the second overvoltage protection circuit.

8. The wireless charging circuit of claim 1, wherein the controller detects a temperature of the wireless charging circuit, and
the first overvoltage protection circuit is turned on when the temperature of the wireless charging circuit is greater than or equal to a first threshold temperature, and the second overvoltage protection circuit is turned on when the temperature of the wireless charging circuit is greater than or equal to a second threshold temperature.

9. The wireless charging circuit of claim 8, wherein the second threshold temperature is greater than the first threshold temperature.

10. The wireless charging circuit of claim 9, wherein a turn-on holding time of the first overvoltage protection circuit is the same as a turn-on holding time of the second overvoltage protection circuit.

11. A wireless charging circuit, comprising:
a power receiving circuit that wirelessly receives power and includes an inductor and a capacitor and;
a rectifier circuit that rectifies an alternating current voltage received from the power receiving circuit and outputs a rectified voltage;
a regulator circuit that outputs a charging voltage that charges a battery using the rectified voltage;
an overvoltage protection circuit connected in parallel between the rectifier circuit and the regulating circuit; and
a controller that detects the rectified voltage and controls the overvoltage protection circuit,
wherein the overvoltage protection circuit includes a first overvoltage protection circuit and a second overvoltage protection circuit, the first overvoltage protection circuit is turned on before the second overvoltage protection circuit, and at least one of the first overvoltage protection circuit or the second overvoltage protection circuit is repeatedly turned-on and turned-off.

12. The wireless charging circuit of claim 11, wherein the first overvoltage protection circuit is repeatedly turned-on and turned-off.

13. The wireless charging circuit of claim 12, wherein a first turn-on time of the second overvoltage protection circuit coincides with a first turn-off time of the first overvoltage protection circuit.

14. The wireless charging circuit of claim 13, wherein a total turn-off holding time of the second overvoltage protection circuit is shorter than a total turn-off holding time of the first overvoltage protection circuit.

15. The wireless charging circuit of claim 13, wherein a total turn-off holding time of the second overvoltage protection circuit is longer than a total turn-off holding time of the first overvoltage protection circuit, and
at least a portion of a turn-off holding time of the second overvoltage protection circuit overlaps with a turn-off holding time of the first overvoltage protection circuit.

16. The wireless charging circuit of claim 12, wherein at least a portion of a turn-on holding time of the second overvoltage protection circuit overlaps with a turn-on holding time of the first overvoltage protection circuit.

17. The wireless charging circuit of claim 12, wherein at least a portion of a turn-off holding time of the second overvoltage protection circuit overlaps with each adjacent turn-off holding time of the first overvoltage protection circuit.

18. The wireless charging circuit of claim 11, wherein the second overvoltage protection circuit is repeatedly turned-on and turned-off.

19. A wireless charging circuit, comprising:
a power receiving circuit that wirelessly receives power and includes an inductor and a capacitor;
a rectifier circuit that rectifies an alternating current voltage received from the power receiving circuit and outputs a rectified voltage;
a regulating circuit that outputs a charging voltage that charges a battery using the rectified voltage;
at least one first overvoltage protection circuit connected in parallel between the rectifier circuit and the regulating circuit and that includes a current source;
at least one second overvoltage protection circuit connected in parallel between the rectifier circuit and the regulating circuit and that includes an external resistor; and
a controller that detects the rectified voltage and controls the overvoltage protection circuit,
wherein the controller turns on the first overvoltage protection circuit when the overvoltage protection circuit satisfies a first operating condition,
turns off the first overvoltage protection circuit and turns on the second overvoltage protection circuit when the overvoltage protection circuit satisfies a second operating condition, and
turns on one of the first overvoltage protection circuit or the second overvoltage protection circuit.

20. The wireless charging circuit of claim 19, wherein
the controller detects a temperature of the wireless charging circuit,
the first operating condition is when the rectified voltage is greater than or equal to a first threshold voltage or when the temperature of the wireless charging circuit is greater than or equal to a first threshold temperature,
the second operating condition is when the rectified voltage is greater than or equal to a second threshold voltage or when the temperature of the wireless charging circuit is greater than or equal to a second threshold temperature, and
the second threshold voltage is greater than the first threshold voltage, and the second threshold temperature is higher than the first threshold temperature.
